(19) United States
(12) Patent Application Publication
(10) Pub. No.: US 2008/0006829 A1
(43) Pub. Date: Jan. 10, 2008

(54) Semiconductor layered structure

(75) Inventors: Dong-Sing Wuu, Taichung City (TW); Ray-Hua Horng, Taichung City (TW); Wei-Kai Wang, Taichung City (TW); Kuo-Sheng Wen, Taichung City (TW)

Correspondence Address: DAVIDSON BERQUIST JACKSON & GOWDEY LLP, 4300 WILSON BLVD., 7TH FLOOR, ARLINGTON, VA, 22203, US

(73) Assignee: Dong-Sing Wuu, Taichung City (TW)

(21) Appl. No.: 11/646,319

(22) Filed: Dec. 28, 2006

(30) Foreign Application Priority Data
Jul. 6, 2006 (TW) 095124658

(51) Int. Cl. H01L 29/15; H01L 31/0256

(52) U.S. Cl. 257/76

(57) ABSTRACT

A semiconductor structure includes: a base layer formed with an array of recesses; a first epitaxial layer stacked on the base layer and extending into the recesses in the base layer; a patterned mask layer stacked on the first epitaxial layer; and a second epitaxial layer having a first portion that corresponds to the recesses in the base layer and that extends through the mask layer to contact the first epitaxial layer, and a second portion that is stacked on the mask layer.

### CROSS-REFERENCE TO RELATED APPLICATION

This application claims the priority of Taiwanese Application No. 095124658, filed on Jul. 6, 2006.

### BACKGROUND OF THE INVENTION

1. Field of the Invention

This invention relates to a semiconductor layered structure, more particularly to a semiconductor layered structure having a low-defect-density epitaxial layer.

2. Description of the Related Art

U.S. Pat. No. 6,608,327 discloses a gallium nitride semiconductor structure that serves as a substrate for growth of an epitaxial cladding layer thereon for reducing the defect (such as the lattice dislocation) density of the epitaxial cladding layer when the epitaxial cladding layer is grown on a sapphire substrate. Referring to FIG. 1, the aforesaid semiconductor structure includes a substrate 102 with an underlying layer 104 of GaN, a patterned first mask layer 106 of SiO₂ formed on the underlying layer 104 and formed with an array of recesses 1061, a first epitaxial layer 108 of GaN having a first portion 108a extending through the recesses 1061 in the mask layer 106 to contact the underlying layer 104 and a second portion 108b stacked on the first mask layer 106, a patterned second mask layer 206 of SiO₂ formed on the first epitaxial layer 108, and a second epitaxial layer 208 of GaN having a first portion 208a extending through the second mask layer 206 to contact the second portion 108b of the first epitaxial layer 108 and a second portion 208b stacked on the second mask layer 206. By forming the recesses 1061 in the first mask layer 106, the defect density at the first portion 108a of the laterally grown first epitaxial layer 108 is significantly reduced. However, reduction of the defect density at the second portion 108b of the first epitaxial layer 108 is not as significant as the first portion 108a of the first epitaxial layer 108. As a consequence, the defect at the second portion 108b of the first epitaxial layer 108 can propagate into the second epitaxial layer 208 formed thereon. Although the second portion 208b of the second epitaxial layer 208 stacked on the second mask layer 206 can further reduce the defect density propagating into the second epitaxial layer 208 formed thereon, the twice regrowth process will largely deteriorate the production yield due to complicated fabrication processes and the semiconductor structure thus formed is relatively complicated too, which results in an increase in the manufacturing costs.

### SUMMARY OF THE INVENTION

Therefore, the object of the present invention is to provide a semiconductor structure and a method for making the same that can overcome the aforesaid drawback of the prior art. The present invention only needs one regrowth process which will benefit the production yield. The array of recesses in the base layer can also provide an optical scattering substrate which will enhance the external quantum efficiency of the light-emitting device fabricated thereon.

According to this invention, there is provided a semiconductor structure that comprises: a base layer formed with an array of recesses; a first epitaxial layer stacked on the base layer and extending into the recesses in the base layer; a patterned mask layer stacked on the first epitaxial layer; and a second epitaxial layer having a first portion that corresponds to the recesses in the base layer and that extends through the mask layer to contact the first epitaxial layer, and a second portion that is stacked on the mask layer.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a schematic view of a conventional semiconductor structure;

FIG. 2 is a schematic view of the preferred embodiment of a semiconductor structure according to this invention; and

FIGS. 3 and 4 are perspective views to illustrate consecutive steps of a method for making the preferred embodiment of this invention.

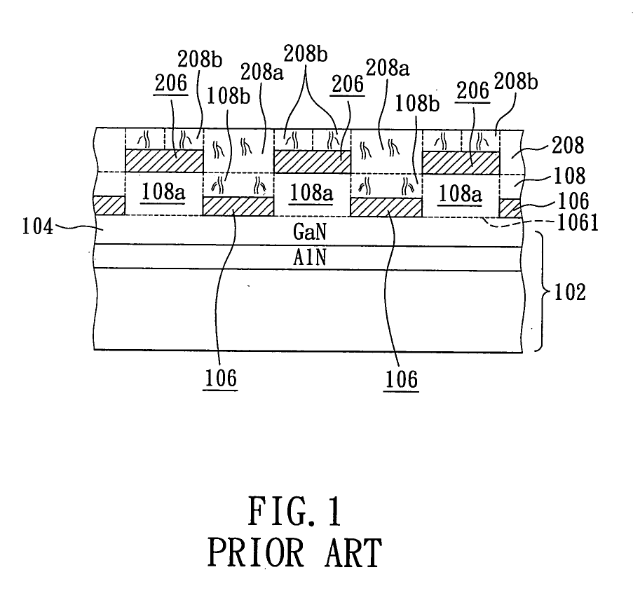

### DETAILED DESCRIPTION OF THE PREFERRED EMBODIMENT

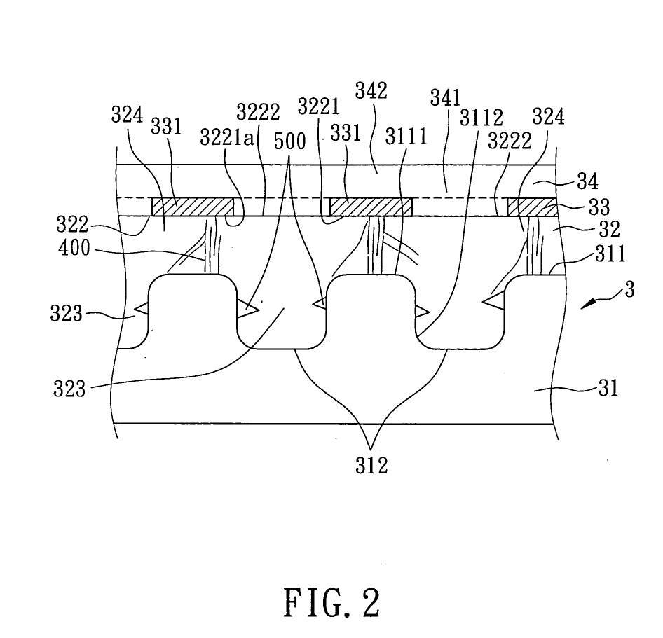

FIG. 2 illustrates the preferred embodiment of a semiconductor structure 3 according to this invention. The semiconductor structure 3 includes: a base layer 31 formed with an array of recesses 312; a first epitaxial layer 32 stacked on the base layer 31 and extending into the recesses in the base layer 31; a patterned mask layer 33 stacked on the first epitaxial layer 32; and a second epitaxial layer 34 having a first portion 341 that corresponds to the recesses 312 in the base layer 31 and that extends through the mask layer 33 to contact the first epitaxial layer 32, and a second portion 342 that is stacked on the mask layer 33.

In this embodiment, the base layer 31 has a film-forming surface 311. The recesses 312 are indented inwardly from the film-forming surface 311 so as to divide the film-forming surface 311 into a continuous recess-free region 3111 and recess-forming regions 3112 which correspond respectively to the recesses 312. The first epitaxial layer 32 is formed on the continuous recess-free region 3111 and the recess-forming regions 3112 of the film-forming surface 311 of the base layer 31. The first epitaxial layer 32 has a mask-forming surface 322 that is opposite to the base layer 31 and that has a film-forming region 3221 corresponding to the continuous recess-free region 3111 of the film-forming surface 311 of the base layer 31, and non-forming regions 3222 corresponding respectively to the recess-forming regions 3112 of the film-forming surface 311 of the base layer 31. The mask layer 33 is formed on the film-forming region 3221 of the mask-forming surface 322 of the first epitaxial layer 32.

The first epitaxial layer 32 has first portions 323 extending respectively into the recesses 312 in the base layer 31, and second portions 324 among the first portions 323. Preferably, a closed cavity 500 is formed between each of the first portions 323 of the first epitaxial 32 and a recess-defining wall of the respective one of the recesses 312. Formation of the closed cavities 500 can be achieved by controlling deposition conditions.

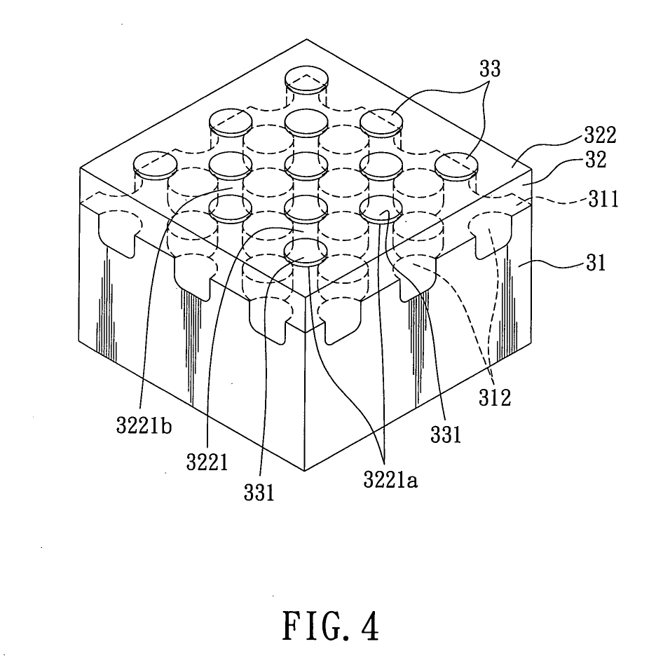

In this embodiment, the mask layer 33 is not a continuous layer, and is comprised of an array of spaced apart mask pads 331. The film-forming region 3221 of the mask-forming surface 322 of the first epitaxial layer 32 has pad-forming sub-regions 3221a (see FIG. 4). The mask pads 331 are stacked respectively on the pad-forming sub-regions 3221a of the film-forming region 3221 of the mask-forming surface 322 of the first epitaxial layer 32 such that the second portions 324 are covered respectively by the mask pads 331. The second epitaxial layer 34 is further stacked on the remaining sub-region 3221b of the film-forming region 3221 of the mask-forming surface 322 of the first epitaxial layer 32.

Preferably, the mask layer 33 is made from a material selected from the group consisting of silicon dioxide, silicon nitride, titanium oxide, tantalum oxide, and has a layer thickness ranging from 0.05 to 1 μm.

Preferably, the base layer 31 is made from a material selected from the group consisting of sapphire, silicon carbide, and silicon, and the first and second epitaxial layers are made from gallium nitride-based semiconductors.

Preferably, each of the recesses 312 in the base layer 31 has a diameter ranging from 0.5 to 5 μm, and a depth, relative to the film-forming surface 311 of the base layer 31, ranging from 0.5 to 2 μm. Each of the recesses 312 in the base layer 31 is spaced apart from an adjacent one of the recesses 312 by a distance ranging from 0.5 to 5 μm.

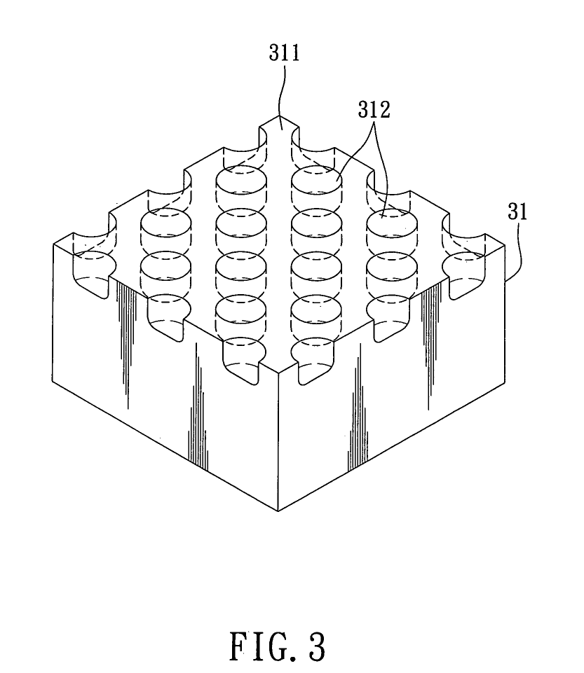

FIGS. 3 and 4, in combination with FIG. 2, illustrate consecutive steps of a method for making the preferred embodiment of this invention. The method includes the steps of: preparing a substrate that serves as the base layer 31 (see FIG. 3); forming the recesses 312 in the base layer 31 through etching via photolithography techniques (see FIG. 3); forming the first epitaxial layer 32 on the base layer 31 through epitaxial lateral overgrowth techniques (see FIG. 4); forming the mask pads 331 of the patterned mask layer 33 on the first epitaxial layer 32 through photolithography techniques (see FIG. 4); and forming the second epitaxial layer 34 on the first epitaxial layer 32 and the mask pads 331 of the mask layer 33 through epitaxial lateral overgrowth techniques (see FIG. 2).

The merits of the semiconductor structure of this invention will become apparent with reference to the following Example.

### EXAMPLE

A sapphire substrate serving as the base layer 31 was masked using a mask of a Ni plate in an inductively coupled plasma etcher. The etcher was conducted at a 1600 W power supplied to an upper electrode and a 350 biased voltage supplied to a lower electrode. The reaction chamber was controlled at a pressure of less than 5 mTorr in the presence of an etchant of a chlorine gas (12 sccm) and a BCl₃ gas (18 sccm) so as to achieve an etching rate of about 300 nm/min. An array of the recesses 312 was formed in the base layer 31 after the etching operation. The first epitaxial layer 32 was subsequently formed on the base layer 31 using metalorganic chemical vapor deposition (MOCVD) techniques. The deposition conditions were controlled so as to permit epitaxial lateral overgrowth of the first epitaxial layer 32. A 0.5 μm layer thickness of the mask layer 33 of silicon carbide was then formed on the first epitaxial layer 32 using plasma assisted chemical vapor deposition (PACVD) techniques. The mask layer 33 thus formed was then patterned through photolithography techniques so as to form the mask pads 331. The second epitaxial layer 34 was then formed on the mask pads 331 of the mask layer 33 and the first epitaxial layer 32 using MOCVD techniques. The deposition conditions were controlled so as to permit epitaxial lateral overgrowth of the second epitaxial layer 34. The semiconductor structure 3 thus formed has a lower defect density as compared to the aforesaid conventional semiconductor structure.

Since the second portions 324 of the first epitaxial layer 32 are covered by the mask pads 331 of the mask layer 33, the defect 400 present in the second portions 324 of the first epitaxial layer 32 is prevented from propagating therethrough and into the second epitaxial layer 34. As such, reduction of the defect density can be further improved in the semiconductor structure 3 of this invention as compared to the aforesaid conventional semiconductor structure.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. A semiconductor structure comprising:
a base layer formed with an array of recesses;
a first epitaxial layer stacked on said base layer and extending into said recesses in said base layer;
a patterned mask layer stacked on said first epitaxial layer; and
a second epitaxial layer having a first portion that corresponds to said recesses in said base layer and that extends through said mask layer to contact said first epitaxial layer, and a second portion that is stacked on said mask layer.

2. The semiconductor structure of claim 1, wherein said base layer has a film-forming surface, said recesses being indented inwardly from said film-forming surface so as to divide said film-forming surface into a continuous recess-free region and recess-forming regions which correspond respectively to said recesses, said first epitaxial layer being formed on said continuous recess-free region and said recess-forming regions of said film-forming surface of said base layer, said first epitaxial layer having a mask-forming surface that is opposite to said base layer and that has a film-forming region corresponding to said continuous recess-free region of said film-forming surface of said base layer, said mask layer being formed on said film-forming region of said mask-forming surface of said first epitaxial layer.

3. The semiconductor structure of claim 2, wherein said mask layer is comprised of an array of spaced apart mask pads, said film-forming region of said mask-forming surface of said first epitaxial layer having pad-forming sub-regions, said mask pads being stacked respectively on said pad-forming sub-regions of said film-forming region of said mask-forming surface, said second epitaxial layer being further stacked on the remaining sub-region of said film-forming region of said mask-forming surface.

4. The semiconductor structure of claim 1, wherein said mask layer is made from a material selected from the group consisting of silicon dioxide, silicon nitride, titanium oxide, titanium nitride, tantalum oxide, tantalum nitride, aluminum nitride, aluminum nitride.

5. The semiconductor structure of claim 1, wherein said mask layer has a layer thickness ranging from 0.05 to 1 μm.

6. The semiconductor structure of claim 1, wherein said base layer is made from a material selected from the group consisting of sapphire, silicon carbide, and silicon, and said first and second epitaxial layers are made from gallium nitride-based semiconductors.

7. The semiconductor structure of claim 1, wherein each of said recesses in said base layer has a diameter ranging from 1 to 5 μm, and a depth, relative to said film-forming surface of said base layer, ranging from 0.5 to 2 μm.

8. The semiconductor structure of claim 7, wherein each of said recesses in said base layer is spaced apart from an adjacent one of said recesses by a distance ranging from 0.5 to 5 μm.
